(19) United States
(12) Patent Application Publication
(10) Pub. No.: US 2025/0336438 A1
(43) Pub. Date: Oct. 30, 2025

(54) MEMORY DEVICE

(71) Applicant: Samsung Electronics Co., Ltd., Suwon-si (KR)

(72) Inventors: Jae Hyun Lim, Suwon-si (KR); Tae-Hyung Kim, Suwon-si (KR); Suk Youn, Suwon-si (KR); Eojin Lee, Suwon-si (KR)

(21) Appl. No.: 19/181,750

(22) Filed: Apr. 17, 2025

(30) Foreign Application Priority Data
Apr. 23, 2024 (KR) 10-2024-0054310
Mar. 28, 2025 (KR) 10-2025-0040184

(51) Int. Cl. G11C 11/419; G11C 5/14; G11C 11/418

(52) U.S. Cl. CPC G11C 11/419; G11C 5/14; G11C 11/418

(57) ABSTRACT

A memory device includes a first bit cell group including a first plurality of bit cells, and a first peripheral circuit group configured to write data to the first plurality of bit cells and read data from the first plurality of bit cells, where the first peripheral circuit group includes a first type transistor and a second type transistor of a different type from the first type transistor, and where the first peripheral circuit group includes a plurality of first standard cells adjacent to each other in a first direction and a first switch cell including one of the first type transistor and the second type transistor.

### CROSS-REFERENCE TO RELATED APPLICATION

This application claims priority to and the benefit of Korean Patent Application No. 10-2024-0054310, filed in the Korean Intellectual Property Office on Apr. 23, 2024, and Korean Patent Application No. 10-2025-0040184, filed in the Korean Intellectual Property Office on Mar. 28, 2025, the entire contents of which are incorporated herein by reference.

### TECHNICAL FIELD

The present disclosure relates to a memory device.

### BACKGROUND

A memory device is a storage device that can record data and read it when necessary. The memory device may include a nonvolatile memory (NVM), in which stored data does not disappear even if power is not supplied, and a volatile memory (VM), in which stored data is destroyed even if power is not supplied. Meanwhile, as electronic devices such as electronic portable devices become smaller, memory devices mounted on electronic devices are also gradually becoming smaller and lighter. As memory devices are down-sized, various research is being conducted to integrate more circuits in limited space.

### SUMMARY

Some embodiments according to the present disclosure attempt to provide a memory device that efficiently utilizes area.

Some embodiments according to the present disclosure seek to provide a memory device that improves a voltage drop (IR-drop) for standard cells in a memory device.

Some embodiments of the present disclosure provide a memory device including: a first bit cell group including a first plurality of bit cells, and a first peripheral circuit group configured to write data to the first plurality of bit cells and read data from the first plurality of bit cells, where the first peripheral circuit group includes a first type transistor and a second type transistor of a different type from the first type transistor, and where the first peripheral circuit group includes a plurality of first standard cells adjacent to each other in a first direction and a first switch cell including one of the first type transistor and the second type transistor.

Some embodiments of the present disclosure provide a memory device comprising: a bit cell group comprising a plurality of bit cells; and a peripheral circuit group, wherein a width of the peripheral circuit group in a first direction is equal to a width of the bit cell group in the first direction, wherein the peripheral circuit group is aligned with the bit cell group in a second direction perpendicular to the first direction, and wherein the peripheral circuit group comprises: a plurality of power rails that are spaced apart from each other in the first direction and extend in the second direction, a plurality of first active regions between a first power rail and a second power rail among the plurality of power rails, wherein plurality of first active regions are spaced apart from each other in the first direction and extend in the second direction and comprise a first transistor and a second transistor having a different type from the first transistor, wherein the first transistor and the second transistor are electrically connected to a first bit cell and a second bit cell, respectively, among the plurality of bit cells, a plurality of second active regions between a third power rail and a fourth power rail among the plurality of power rails, wherein the plurality of second active regions are spaced apart from each other in the first direction and extend in the second direction and comprise a third transistor and a fourth transistor having a different type from the third transistor, wherein the third transistor and the fourth transistor are electrically connected to a third bit cell and a fourth bit cell, respectively, among the plurality of bit cells, and a third active region between the second power rail and third power rail, wherein the second power rail and the third power rail are adjacent to each other, wherein the third active region is spaced apart from the second power rail and the third power rail in the first direction by a same distance in the first direction and extends in the second direction, and wherein the third active region comprises a fifth transistor.

Some embodiments of the present disclosure provide a memory device including: a plurality of bit cells having a first width in a first direction, a plurality of standard cells having a second width in the first direction different from the first width, wherein the plurality of standard cells electrically connected to the plurality of bit cells through bit lines, where the plurality of standard cells include a plurality of active regions, where each of the plurality of active regions includes a first type transistor and a second type transistor different from the first type transistor, a height in the first direction of each of the plurality of standard cells is based on a width of a respective active region of the plurality of active regions in the first direction, and wherein the plurality of standard cells are aligned in the first direction, and a non-standardized cell aligned with the plurality of standard cells in the first direction and having a height equal to the difference between a length of the first width and a length of the second width.

### BRIEF DESCRIPTION OF THE DRAWINGS

FIG. 1 illustrates a block diagram of a memory device according to some embodiments.

FIG. 2 illustrates a layout diagram of the memory device according to some embodiments.

FIG. 3 illustrates a circuit diagram for describing a bit cell of a semiconductor device according to some embodiments of the present disclosure.

FIG. 4 illustrates a layout diagram of the semiconductor device according to a comparative embodiment.

FIG. 5 illustrates a layout diagram of standard cells of a peripheral circuit group.

FIG. 6 illustrates a diagram for describing a switch cell among standard cells in a peripheral circuit group according to a comparative embodiment.

FIG. 7 illustrates a diagram for describing a switch cell among standard cells in a peripheral circuit group according to a comparative embodiment.

FIG. 8 illustrates a layout diagram of a semiconductor device according to some embodiments.

FIG. 9 illustrates a layout diagram of standard cells of a peripheral circuit group according to some embodiments.

FIG. 10 illustrates a cross-sectional view of a standard cell and a switch cell according to some embodiments.

FIG. 11 illustrates a layout diagram of a memory device according to some embodiments.

FIG. 12 illustrates a layout diagram of the memory device according to some embodiments.

FIG. 13 illustrates a layout diagram of a memory device according to some embodiments.

FIG. 14 illustrates a layout diagram of the memory device according to some embodiments.

FIG. 15 illustrates a block diagram showing a computing system that manufactures a memory device according to some embodiments.

FIG. 16 illustrates a layout diagram of the memory device according to some embodiments.

FIG. 17 illustrates a layout diagram of the memory device according to some embodiments.

### DETAILED DESCRIPTION

In the following detailed description, only certain embodiments of the present disclosure have been shown and described, simply by way of illustration. As those skilled in the art would realize, the described embodiments may be modified in various different ways, all without departing from the spirit or scope of the present disclosure.

It should be understood that the embodiments described herein are intended to implement various features of the present disclosure. These are of course merely examples and are not intended to be limiting. For example, the dimensions of the components are not limited to the published ranges or values and may vary depending on process conditions and/or desired device properties. In addition, in the following description, the formation of the first structure on or above the second structure may include embodiments in which the first and second structures are formed in direct contact, and embodiments may also include where additional structures may be formed between the first and second structures such that the first and second structures are not in direct contact. For simplicity and clarity, various structures may be drawn arbitrarily at different scales.

In addition, spatially related terms, such as “below”, “lower”, “lower portion”, “above”, “upper portion”, etc., may be used for ease of description to depict the relationship of any one element or structure illustrated in the drawing to another element or structure. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Accordingly, the drawings and description are to be regarded as illustrative in nature and not restrictive. Like reference numerals designate like elements throughout the specification.

In addition, expressions written in the singular, such as “a”, “an,” or “the,” may be construed in the singular or plural unless an explicit expression such as “one” or “single” is used. Terms including ordinal numbers such as first, second, and the like will be used only to describe various component and are not to be interpreted as limiting these components. These terms may be used for the purpose of distinguishing one constituent element from other constituent elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The term “and/or” includes any and all combinations of one or more of the associated listed items. The term “connected” may be used herein to refer to a physical and/or electrical connection and may refer to a direct or indirect physical and/or electrical connection.

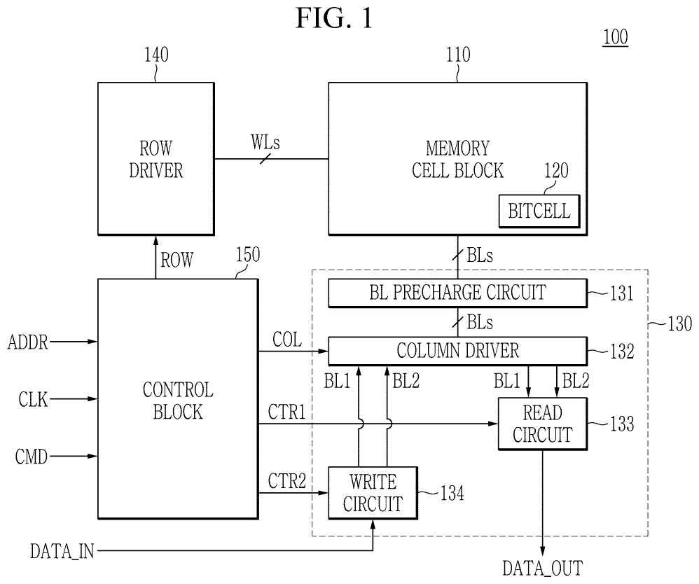

FIG. 1 illustrates a block diagram of a memory device according to some embodiments.

Referring to FIG. 1, the memory device 100 may receive a command CMD, an address ADDR, a clock CLK, and write data DATA_IN, and may output read data DATA_OUT. For example, the memory device 100 may receive a command CMD instructing write (may be referred to hereinafter as a write command), an address (may be referred to hereinafter as a write address), and write data DATA_IN, and the write data DATA_IN may be stored in an area of a memory cell block 110 corresponding to an address. Additionally, the memory device 100 may receive a command (CMD) instructing read (may be referred to hereinafter as a read command) and an address (may be referred to hereinafter as a read address), and may externally output read data DATA_OUT stored in the area of the memory cell block 110 corresponding to the address.

The memory cell block 110 may include a plurality of bit cells 120. Each of the bit cells 120 may be connected to one of a plurality of word lines WLs and to at least one of a plurality of bitlines BLs.

A row driver 140 may be connected to the memory cell block 110 through the word lines WLs. The row driver 140 may activate one word line among the word lines WLs based on a row address ROW. Accordingly, among the memory cells, memory cells connected to the activated word line may be selected. That is, the row driver 140 may select any one word line among the word lines WLs.

A control block 150 may receive a command CMD, an address ADDR, and a clock CLK, and may generate a row address ROW, a column address COL, a first control signal CTR1, and a second control signal CTR2. For example, the control block 150 may identify a read command by decoding the command CMD, and may generate the row address ROW, the column address COL, and the first control signal CTR1 to read data DATA_OUT from the memory cell block 110. In addition, the control block 150 may identify the write command by decoding the command CMD, and may generate the row address ROW, the column address COL, and the second control signal CTR2 to write data DATA_IN in the memory cell block 110.

An input/output block 130 may include a bitline precharge circuit 131, a column driver 132, a read circuit 133, and a write circuit 134.

The bitline precharge circuit 131 may be connected to the memory cell block 110 through the bit lines BLs. The bitline precharge circuit 131 may precharge the bitlines BLs. The bitlines BLs may include a bitline and a bitline bar complementary to the bitline connected to opposite ends of the memory cell.

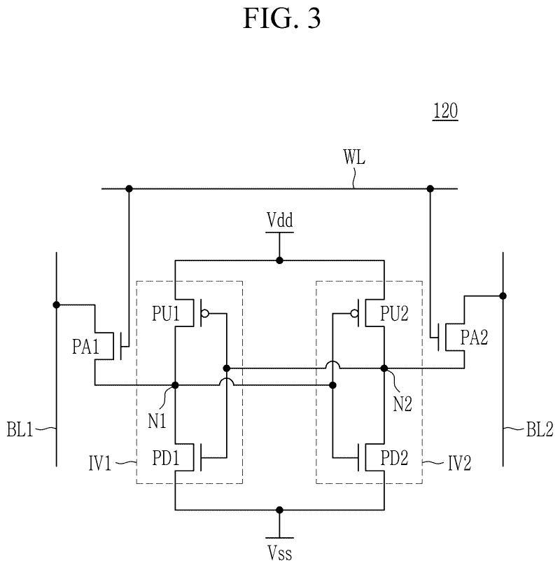

The column driver 132 may be connected to the bitline precharge circuit 131 through the bitlines BLs. The column driver 132 can select at least one bitline among the bitlines BLs based on the column address COL. As at least one bitline is selected among the bitlines BLs, the bit cell 120 connected to the selected bitline among the bitcells 120 may be selected. At least one bitline may include a first bitline BL1 and a second bitline BL2 that is complementary to the first bitline BL1. The first bitline BL1 and the second bitline BL2 may be connected to opposite ends of the bit cell 120 of the memory cell block 110. A connection relationship between the bit cell 120 and the first bitline BL1 and the second bitline BL2 will be described later with reference to FIG. 3.

The read circuit 133 may detect the current and/or voltage received through the bit lines BLs during a read operation, may identify a value connected to the activated word line, i.e., stored in the selected bit cell 120, and may output read data DATA_OUT based on the identified value. The read circuit 133 may be connected to the column driver 132 through at least one bitline among the bitlines BLs. At least one bitline may include a first bitline BL1 and a second bitline BL2. The read circuit 133 may receive the first control signal CTR1 from the control block 150. The read circuit 133 may include a sense amplifier.

The write circuit 134 may apply a current and/or a voltage to the bitlines BLs based on the write data DATA_IN during a write operation, and may write a value to the selected bit cell 120 connected to the activated word line. The write circuit 134 may be connected to the column driver 132 through at least one bitline among the bitlines BLs. At least one bitline may include a first bitline BL1 and a second bitline BL2. The write circuit 134 may receive the second control signal CTR2 from the control block 150.

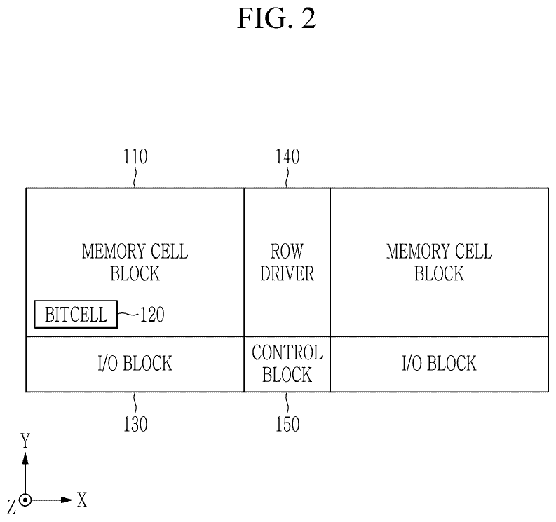

FIG. 2 illustrates a layout diagram of the memory device according to some embodiments.

The memory device 100 may include the memory cell block 110, the input/output block 130, the row driver 140, and the control block 150. The memory cell block 110 may include a plurality of bit cells 120 each accessed by a word line and a bitline. In some embodiments, the bit cell 120 may be a volatile memory cell, such as a static random access memory (SRAM), a dynamic random access memory (DRAM), etc. Embodiments of the present disclosure will be described primarily with reference to an SRAM cell, but the present disclosure is not limited thereto.

Referring to FIG. 2, the row driver 140 may be positioned adjacent to the memory cell block 110 in a first direction X. The row driver 140 may be positioned between the memory cell blocks 110 in the first direction X. The row driver 140 may access the bit cell 120 through a word line. The input/output block 130 may be positioned adjacent to the memory cell block 110 in a second direction Y perpendicular to the first direction X. The input/output block 130 may perform the write or read operation. The control block 150 may be positioned adjacent to the input/output block 130 in the first direction X and adjacent to the row driver 140 in the second direction Y. The control block 150 may be positioned between the input/output blocks 130 in the first direction X. The input/output block 130 may transmit signals to perform the write or read operation.

Hereinafter, the input/output block 130, the row driver 140, and the control block 150 excluding the memory cell block 110 of the memory device 100 may be referred to as a peripheral circuit. The peripheral circuit may include a plurality of standard cells. A standard cell, which is a unit of layout, may be designed to perform a predefined function. A standard cell may refer to a standardized cell with a predetermined size and may be provided from a cell library. In some embodiments, the bit cells of the memory cell block 110 of the memory device 100 may form a plurality of bit cell groups, and a plurality of standard cells of the peripheral circuit may form a plurality of peripheral circuit groups.

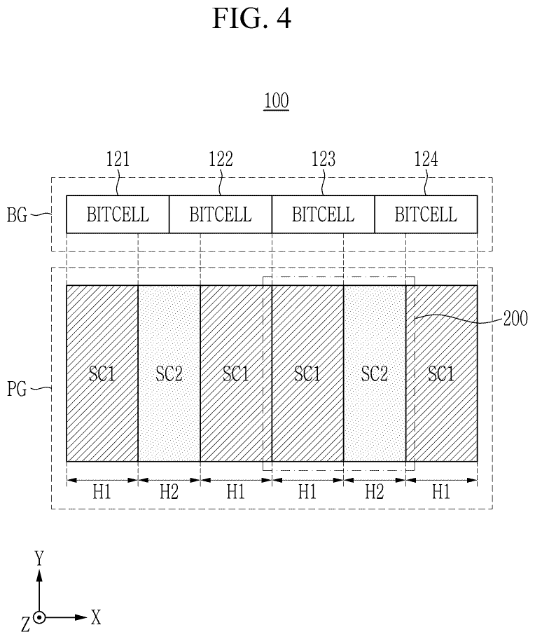

In some embodiments, the standard cells of the peripheral circuit group may write data to the bit cells of the memory cell block 110 or read data from the bit cells. The peripheral circuit groups may include switch cells. For example, a switch cell may perform a power gating operation that selectively provides a power voltage to the standard cells. In some embodiments, the switch cell may be implemented with a P-type transistor or an N-type transistor. The bit cell groups and the peripheral circuit groups will be described later with reference to FIG. 4.

FIG. 3 illustrates a circuit diagram for describing a bit cell of a semiconductor device according to some embodiments of the present disclosure. The bit cell 120 may be included in the memory cell block 110 of FIGS. 1 and 2, and may refer to the bit cell 120 of FIGS. 1 and 2. Herein, the bit cell 120 may be an SRAM bit cell, but the present disclosure is not limited thereto.

Referring to FIG. 3, the bit cell 120 may include a first pull-up transistor PU1, a first pull-down transistor PD1, a second pull-up transistor PU2, a second pull-down transistor PD2, a first pass transistor PA1, and a second pass transistor PA2. The first pull-up transistor PU1 and the second pull-up transistor PU2 are P-type transistors, and the first pull-down transistor PD1, the second pull-down transistor PD2, and the first pass transistor PA1 and the second pass transistor PA2 may be N-type transistors, but the present disclosure is not limited thereto.

The first pull-up transistor PU1 and the first pull-down transistor PD1 may constitute a first inverter IV1. Gates of the first pull-up transistor PU1 and the first pull-down transistor PD1 may be connected to each other. The gates of the first pull-up transistor PU1 and the first pull-down transistor PD1 connected to each other may correspond to an input terminal of the first inverter IV1. A first node N1 may correspond to an output terminal of the first inverter IV1.

The second pull-up transistor PU2 and the second pull-down transistor PD2 may constitute a second inverter IV2. Gates of the second pull-up transistor PU2 and the second pull-down transistor PD2 may be connected to each other. The gates of the second pull-up transistor PU2 and the second pull-down transistor PD2 connected to each other may correspond to an input terminal of the second inverter IV2. A second node N2 may correspond to an output terminal of the second inverter IV2.

The first inverter IV1 and the second inverter IV2 may be combined to form a latch structure. The gates of the first pull-up transistor PU1 and the first pull-down transistor PD1 may be electrically connected to the second node N2, and the gates of the second pull-up transistor PU2 and the second pull-down transistor PD2 may be electrically connected to the first node N1. That is, an input terminal of the first inverter IV1 is connected to an output terminal of the second inverter IV2, and an input terminal of the second inverter IV2 may be connected to an output terminal of the first inverter IV1.

A source and a drain of the first pass transistor PA1 may be connected to the first node N1 and a first bitline BL1, respectively. A source and a drain of the second pass transistor PA2 may be connected to the second node N2 and a second bitline BL2, respectively. The second bitline BL2 may be complementary to the first bitline BL1. The gates of the first pass transistor PA1 and the second pass transistor PA2 may be electrically connected to the word line WL.

In the bit cell 120, when a potential of the word line WL reaches a first level (e.g., logic high), the first pass transistor PA1 and the second pass transistor PA2 may be turned on, and signals of the bitline BL and the complementary bit line BLB may be transmitted to the first inverter IV1 and the second inverter IV2, respectively, to be operated to write or read data.

FIG. 4 illustrates a layout diagram of the semiconductor device according to a comparative embodiment. Specifically, it is a layout that describes a bit cell group BG included in the memory device 100 and a peripheral circuit group PG corresponding to the bit cell group BG and included in a peripheral circuit in an X-Y plane. The bit cell group BG and the peripheral circuit group PG may be repeatedly arranged multiple times along the first direction X, but for simplicity of description, one bit cell group BG and one peripheral circuit group PG are shown herein.

Referring to FIG. 4, the bit cell group BG may include a predetermined number of bit cells arranged adjacently in the first direction X. For example, the bit cell group BG may include four bit cells 121, 122, 123, and 124, but a number of bit cells included in the bit cell group is not limited thereto. The bit cells 121, 122, 123, and 124 may be electrically connected to standard cells arranged in the peripheral circuit group PG through bitlines and complementary bitlines (e.g., standard cells in which circuits constituting the input/output block 130 of FIGS. 1 and 2 are implemented).

The peripheral circuit group PG may include a predetermined number of standard cells SC arranged adjacently in the first direction X. The standard cells SC may include logic cells such as switch cells or inverters. A standard cell, which is a unit of layout, may be designed as a CMOS transistor including a P-type transistor and an N-type transistor. The standard cells arranged in the peripheral circuit group PG may implement peripheral circuits that write or read data to or from the bit cell.

The peripheral circuit group PG may correspond to the bit cell group BG. That is, the peripheral circuit group PG and the bit cell group BG may be aligned with each other in the second direction Y and have a same width in the first direction X. In FIG. 4, the four bit cells 121, 122, 123, and 124 of the bit cell group BG are shown as corresponding to the six standard cells SC of the peripheral circuit group PG, but a ratio between the bit cells and the standard cells is not limited thereto, and may be modified in various ways.

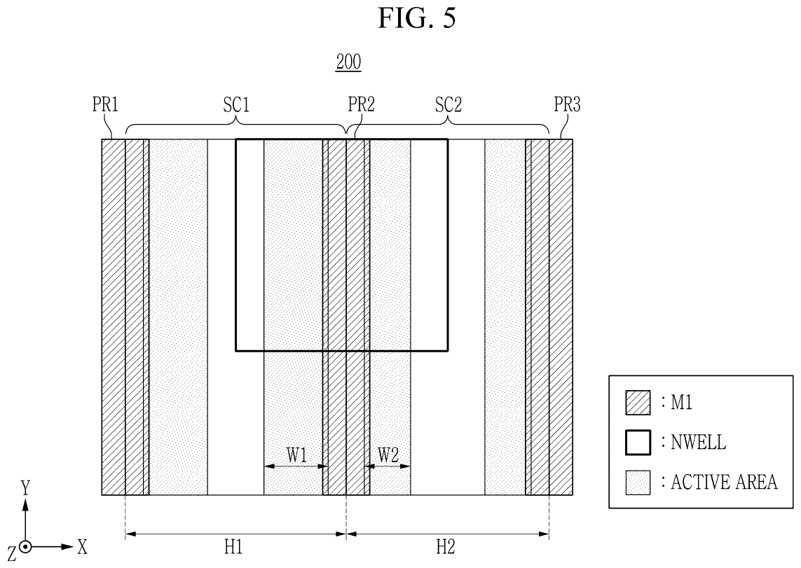

Meanwhile, the peripheral circuit group PG may include standard cells having different heights in order to increase integration of the standard cells positioned in a predetermined area corresponding to the bit cell group BG. Herein, a height of the standard cells may refer to a length of the standard cell in an X-axis direction. For example, a first standard cell SC1 may have a first height H1, and a second standard cell SC2 may have a second height H2. In this case, the first height H1 may be greater than the second height H2. The height of the standard cells may vary depending on a driving force or power of the standard cells. Among the standard cells, the height of a standard cell that requires a relatively large driving force or power may be greater than the height of a standard cell that requires a relatively small driving force or power. For example, the first height H1 corresponds to a first driving force or power, the second height H2 corresponds to a second driving force or power, and the first driving force or power may be greater than the second driving force or power. In FIG. 4, the peripheral circuit group PG is shown as including standard cells with two different heights, but the present disclosure is not limited thereto, and the peripheral circuit group PG may include standard cells with three or more different heights. An internal structure of standard cells 200 included in the peripheral circuit group PG will be described with reference to FIG. 5.

FIG. 5 illustrates a layout diagram of standard cells of a peripheral circuit group.

Referring to FIG. 5, the peripheral circuit group may include the first standard cell SC1 of the first height H1 and the second standard cell SC2 of the second height H2. A plurality of power rails, e.g., first to third power rails PR1 to PR3, that supply voltages to the standard cells may be positioned at a boundary of each standard cell 200. The first to third power rails PR1 to PR3 may be formed as a conductive pattern extending in the second direction Y and may be arranged to be spaced apart from each other in the first direction X. A power voltage and a ground voltage may be applied to the power rails. For example, the power voltage may be applied to the first and third power rails PR1 and PR3, and the ground voltage at a level lower than the power voltage may be applied to the second power rail PR2. Each standard cell may receive the power voltage and the ground voltage through the power rails.

The standard cells 200 may include a plurality of active regions extending in the second direction Y and spaced apart from each other in the first direction X. The first standard cell SC1 and the second standard cell SC2 may each include two active regions. The height of the standard cells 200 may be determined by a width of the active region included in the standard cell in the first direction X. For example, a width W1 of the active region included in the first standard cell SC1 in the first direction X is larger than a width W2 in the first direction of the active region included in the second standard cell SC2, and thus the first height H1 of the first standard cell SC1 may be greater than the second height H2 of the second standard cell SC2.

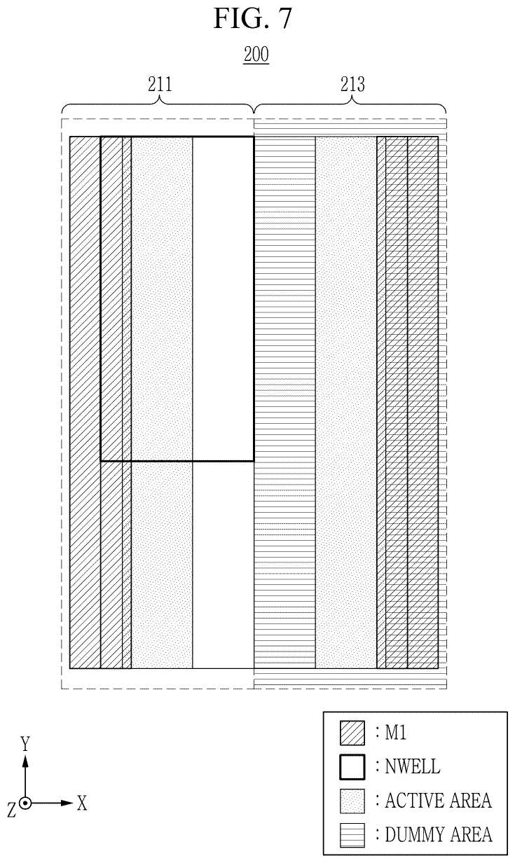

An active pattern formed in the active region may cross a gate line to form a transistor. For example, an N-type transistor may be formed in an active region formed on a substrate, and a P-type transistor may be formed in an active region formed in an n well (shown as NWELL in FIG. 7) doped with an N-type impurity. The n well may be formed across different standard cells. For example, one n well may be formed across the first standard cell SC1 and the second standard cell SC2, but the n well may be formed in various shapes depending on the disposition and number of transistors.

Meanwhile, as described above, widths of the peripheral circuit group PG and the bit cell group BG in the first direction may be the same, in order to increase the integration of the standard cells SC in the peripheral circuit group PG, heights of the standard cells SC designed as CMOS transistors may be different depending on the driving power of the standard cells SC. However, heights of some of the standard cells may be determined to be greater than a height due to the driving force or power required for the standard cell in order to keep the widths of the peripheral circuit group PG and the bit cell group BG the same in the first direction. For example, assuming that the first driving force or power is greater than the second driving force or power, a driving force or power required for the first standard cell SC1 is the second driving force or power, although the first standard cell SC1 may be implemented with the second height H2, the first standard cell SC1 with the first height H1 corresponding to the first driving force or power may be positioned to maintain the same widths of the peripheral circuit group PG and bit cell group BG in the first direction.

An active pattern formed in the active region within the standard cell may be formed in various shapes. For example, a standard cell may be formed as a gate-all-around (GAA) transistor in which a nanowire on the active region is surrounded by a gate line, a plurality of nanosheets may be stacked on the active region, and a gate line may be formed as a multi bridge channel (MBC) transistor surrounding the nanosheets. In this case, a maximum size of the nanowire or nanosheet is predetermined, so a size of the transistor may not be adjusted beyond the maximum size of the nanowire or nanosheet. That is, the width of the active region may not be increased beyond the maximum size of the nanowire or nanosheet. However, there is a problem in which some space in some standard cells is wasted as empty space by increasing the height of some standard cells to keep the widths of the peripheral circuit group PG and the bit cell group BG in the first direction X the same despite the fixed maximum size of the transistor.

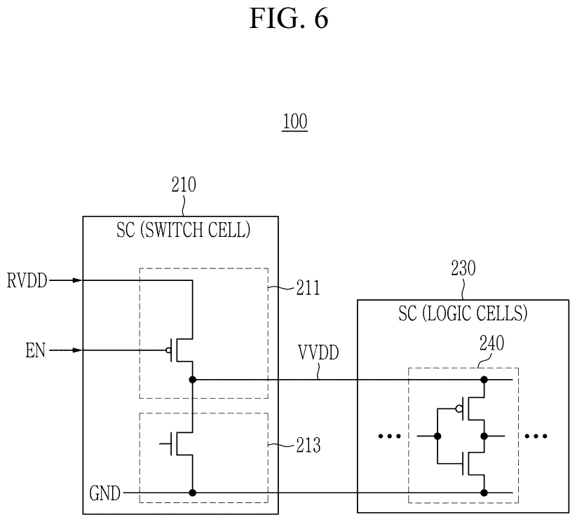

A problem of wasted space within a standard cell also exists in standard cells implemented as switch cells. Next, this will be described later with reference to FIG. 6 and FIG. 7.

FIG. 6 and FIG. 7 illustrate a diagram for describing a switch cell among standard cells in a peripheral circuit group according to a comparative embodiment. Specifically, FIG. 6 illustrates a circuit diagram for describing a switch cell, and FIG. 7 illustrates a layout diagram of the switch cell.

Referring to FIG. 6, a standard cell in the peripheral circuit group of the memory device 100 may include a switch cell 210 and a logic cell 230. Herein, the switch cell 210 is a power gating cell, and hereinafter, an operation of the switch cell 210 is shown and described as being implemented with a P-type transistor, but the present disclosure is not limited thereto, and the switch cell 210 may be implemented with an N-type transistor.

The switch cell 210 may receive a first voltage RVDD from the outside, and may output a second voltage VVDD based on an enable signal EN. The switch cell 210 may operate as a power gating cell by selectively outputting the second voltage VVDD based on the enable signal EN. Voltage levels of the first voltage RVDD and the second voltage VVDD may be the same. The switch cell 210 may provide the second voltage VVDD to the logic cell 230. A CMOS transistor 240 in the logic cell 230 may receive the second voltage VVDD from the switch cell 210, and may receive a ground voltage GND from the outside.

Meanwhile, according to the comparative embodiment, standard cells within the peripheral circuit group of the memory device 100 may be designed as CMOS transistors. Accordingly, the switch cell 210 may include a P-type transistor 211 and an N-type transistor 213. However, since an operation of the switch cell 210 can be implemented only with the P-type transistor 211, a region of the N-type transistor 213 within the switch cell 210 may exist as a dummy region.

Referring to FIG. 7, the switch cell 210 in the peripheral circuit group according to the comparative embodiment may include the P-type transistor 211 and the N-type transistor 213, and the region of the N-type transistor 213 within the switch cell 210 may exist as a dummy region. In other words, there is a problem in which space equivalent to the size of the N-type transistor 213 is wasted within the switch cell 210.

According to some embodiments, the height of the standard cells in the peripheral circuit group is determined according to the driving force or power of the standard cells, and a P-type or N-type transistor may be positioned in a remaining region within the peripheral circuit group. According to some embodiments, the peripheral circuit group may include a switch cell designed with only a P-type or N-type transistor.

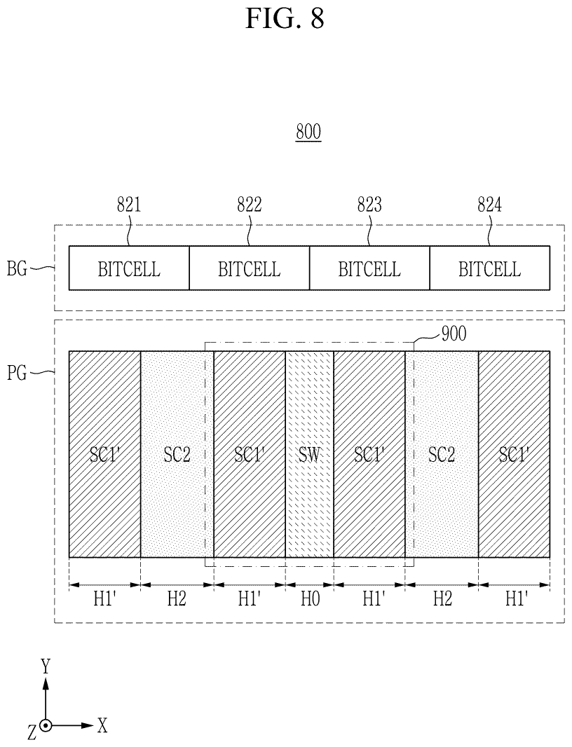

FIG. 8 illustrates a layout diagram of a semiconductor device according to some embodiments. Specifically, a peripheral circuit group PG according to some embodiments may include a standard cell SC1′ with a height determined according to the driving force or power of the standard cells and a switch cell designed with only a P-type or N-type transistor.

In some embodiments, the peripheral circuit group PG may include a first standard cell SC1′ of a third height H1′ and a second standard cell SC2 of a second height H2 according to the driving force or power. The first standard cell SC1′ according to some embodiments indicates that the first standard cell SC1 according to the comparative embodiment of FIG. 4 has a height determined according to the driving force or power required for the first standard cell SC1. For example, assuming that a third driving force or power is required for the first standard cell SC1′, the first standard cell SC1′ may have a third height H1′ determined according to the third driving force or power required for the first standard cell SC1′. Accordingly, a width in the first direction X of the bit cells 821, 822, 823, 824 may be different than a width in the first direction X of the standard cells SC. A width in the first direction X of the bit cells 821, 822, 823, 824 may be longer or greater than a width in the first direction X of the standard cells SC. That is, the peripheral circuit group PG according to some embodiments may include the first standard cell SC1′ with the third height H1′ and the second standard cell SC2 with the second height H2 according to the driving force or power, thereby acquiring a remaining space as much as a fourth height H0. The fourth height H0 may be equal to the difference between the width in the first direction X of the bit cells 821, 822, 823, 824 and the width in the first direction X of the standard cells SC.

The peripheral circuit group PG according to some embodiments may include a P-type transistor or an N-type transistor. The peripheral circuit group PG according to some embodiments may include a switch cell SW designed with only a P-type transistor or an N-type transistor. The peripheral circuit group PG may position a plurality of standard cells with a height determined according to the driving force or power, and may position only a P-type transistor or an N-type transistor alone in a remaining space obtained. In some embodiments, the fourth height H0 may be a minimum height for implementing a P-type transistor or N-type transistor. That is, the minimum height H0 for positioning a P-type transistor or N-type transistor in the peripheral circuit group PG may be secured by determining the height of the standard cells SC according to the driving force or power of the standard cells SC in the peripheral circuit group PG. In FIG. 8, a P-type transistor or N-type transistor implemented as a switch cell SW is shown as being positioned between the standard cells in the peripheral circuit group PG, but the present disclosure is not limited thereto, and a P-type transistor or N-type transistor implemented as a switch cell SW may be positioned at an edge of the peripheral circuit group PG.

In some embodiments, the peripheral circuit group PG may obtain a space larger than the fourth height H0 as a remaining space after determining the height of the standard cells SC in the peripheral circuit group PG according to the driving force or power of the standard cells SC. For example, the peripheral circuit group PG may obtain a space larger than an integer multiple of the fourth height H0 by determining the height of the standard cells SC according to the driving force or power of the standard cells SC in the peripheral circuit group PG. In some embodiments, a plurality of switch cells SW may be positioned in the remaining space after determining the height of the standard cells SC. For example, the peripheral circuit group PG may position the switch cells SW in a plurality of positions where the switch cells SW are required. The peripheral circuit group PG may position the switch cells SW implemented with only P-type transistors or N-type transistors at positions where switch cells SW are needed. The memory device 800 according to some embodiments may obtain the remaining space by determining the height of the standard cells SC according to the driving force or power of the standard cells SC, and an area of the memory device 800 may be utilized efficiently by positioning only the P-type transistor or N-type transistor as the switch cell SW at the position where the switch cell SW is needed. Additionally, when the switch cell SW operates as a power gating cell, there is an advantage in improving voltage drop IR-drop for the standard cells within the peripheral circuit group PG.

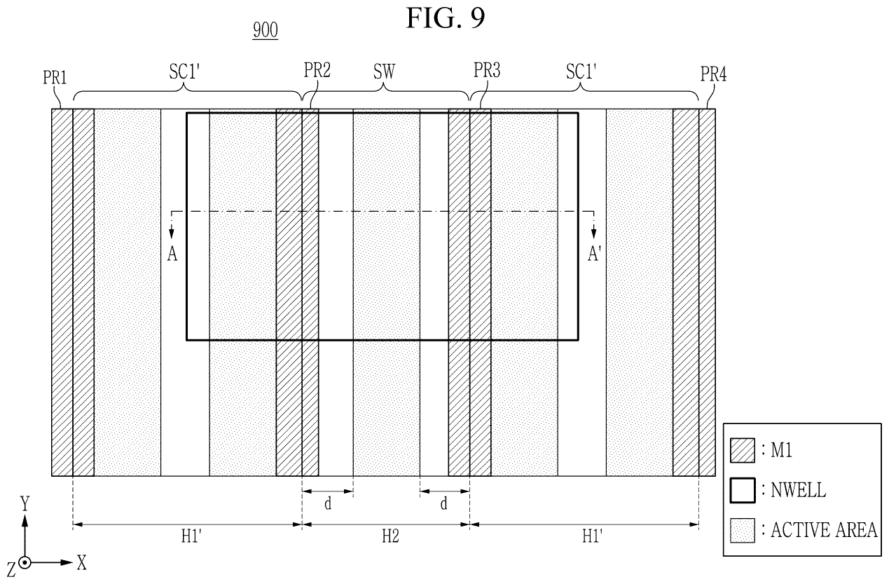

The memory device 800, which includes bit cells 821, 822, 823, 824, according to some embodiments may increase a number of the standard cells implemented as logic cells by optimizing the size of the standard cells included in the peripheral circuit group PG corresponding to the bit cell group BG, efficiently utilizing an area of the memory device 800. An internal structure of standard cells 900 included in the peripheral circuit group PG according to some embodiments of the present disclosure will be described with reference to FIG. 9.

FIG. 9 illustrates a layout diagram of standard cells of a peripheral circuit group according to some embodiments. Meanwhile, descriptions duplicating that of the layout diagram according to FIG. 4 will be omitted herein.

In some embodiments, the peripheral circuit group may include first standard cells SC1′ of a third height H1′ and switch cells SW positioned between the first standard cells SC1′. At boundaries of the first standard cells SC1′, the first to fourth power rails PR1 to PR4 extending in the second direction Y and spaced apart from each other in the first direction X may be positioned to supply a power voltage and a ground voltage to the standard cells. The first standard cells SC1′ may include a plurality of active regions extending in the second direction Y and spaced apart from each other in the first direction X. An N-type transistor may be formed in an active region formed on a substrate, and a P-type transistor may be formed in an active region formed in an n well doped with an N-type impurity, and n wells may be formed across different standard cells. Herein, the third height H1′ of the first standard cells SC1′ may be a height determined according to a driving force or power of the first standard cells SC1′.

In some embodiments, the peripheral circuit group may include a P-type transistor implemented as a switch cell SW positioned in a remaining space obtained by optimizing the height of the standard cells. The switch cell SW may include an active region extending in the second direction Y. An active region of the switch cell SW may be positioned at an equal distance d apart from the power rails PR2 and PR3 positioned adjacent to the switch cell SW. In FIG. 9, the distance d is shown as a distance from a center of the power rails PR2 and PR3 to an edge of the active area, but the present disclosure is not limited thereto, and the distance d may be based on various points, such as from the center of the power rails PR2 and PR3 to a center of the active region.

In some embodiments, the switch cell SW may share a n well with adjacent first standard cells SC1′. The switch cell SW may share the power rails PR2 and PR3 with the adjacent first standard cells SC1′. For example, at least one of the power rails PR2 and PR3 may be a power rail that supplies a power voltage. The switch cell SW may output the second voltage VVDD to at least one of the power rails PR2 and PR3 based on the first voltage RVDD and the enable signal EN received from the outside.

Meanwhile, unlike in FIGS. 8 and 9, standard cells of various heights may be arranged around the switch cell SW, and n wells may be formed in various shapes depending on the disposition and types of the switch cell and the standard cells.

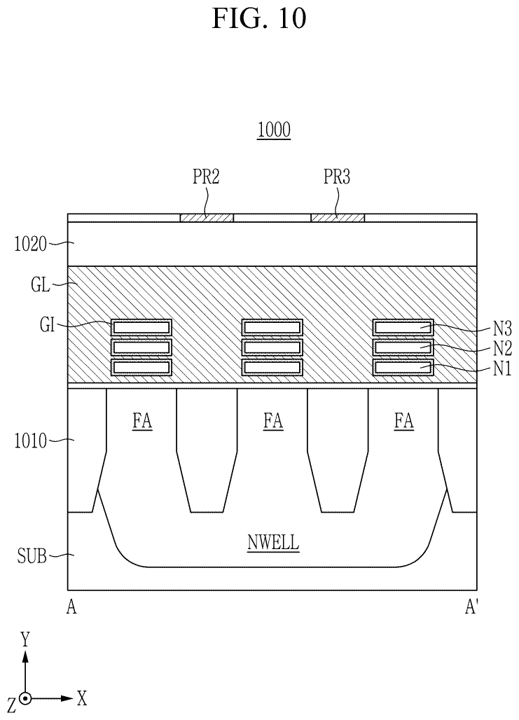

FIG. 10 illustrates a cross-sectional view of a standard cell and a switch cell according to some embodiments. Specifically, it illustrates a cross-sectional view taken along line A-A′ in FIG. 9, showing an example in which a nanosheet is formed as an active pattern in an active region. However, the memory device according to the present disclosure is not limited thereto.

Referring to FIG. 10, in some embodiments, a plurality of active regions FA extending in the second direction Y may be formed on a substrate SUB, and a nanosheet stacking structure in which a plurality of nanosheets N1, N2, and N3 are stacked may be formed on each upper portion of the active regions FA.

The plurality of active regions FA on the substrate SUB may be formed in the n wells NWELL formed within the substrate SUB. A trench 1010 defining the active region FA may be formed between the active regions FA. The active regions FA may be separated from each other by the trench 1010.

In some embodiments, the nano sheets N1, N2, and N3 may be formed on top of each of the active regions FA. The nano sheets N1, N2, and N3 may be arranged to be spaced apart from the active regions FA in the second direction Y. Each of the nanosheet N1, N2, and N3 may extend in the first direction X on the active regions FA. Each of the nano sheets N1, N2, and N3 may be stacked one by one on the active regions FA, and may function as a channel of the transistor. For example, if N-type impurities are doped in the nano sheets N1, N2, and N3, a P-type transistor may be formed, and if P-type impurities are doped, an N-type transistor may be formed. Meanwhile, herein, three nanosheets N1, N2, and N3 are shown forming a nanosheet stacking structure, but the present disclosure is not limited thereto. In addition, herein, a planar shape of the nano sheets N1, N2, and N3 may be shown to have an approximately quadrangular shape, but the present disclosure is not limited thereto, and the nano sheets N1, N2, and N3 may have various planar shapes depending on planar shapes of the active regions FA and planar shapes of gates GI and GL. The nanosheets N1, N2, and N3 may be made of silicon (Si), germanium (Ge), or silicon-germanium (SiGe), and may also be made of InGaAs, InAs, GaSb, InSb, or a combination thereof.

The gates GI and GL may be formed to surround at least a portion of the nanosheets N1, N2, and N3. For example, the gates GI and GL may include a gate line GL surrounding nanosheets N1, N2, and N3 and a gate insulating film GI formed between nanosheets N1, N2, and N3 and the gate line GL.

An interlayer insulating layer 1020 may be disposed on the gate line GL, and the gate line GL may be connected to the power rails PR2 and PR3 of the first metal layer through a gate contact and a gate via (not shown) formed to extend through the interlayer insulating layer 1020.

Referring to FIG. 9, the P-type transistor formed in a center among the transistors shown in FIG. 10 may be a switch cell SW. That is, unlike other standard cells designed with CMOS transistors, the switch cell SW is implemented as a P-type transistor, which has an advantage of optimizing an area of the memory device.

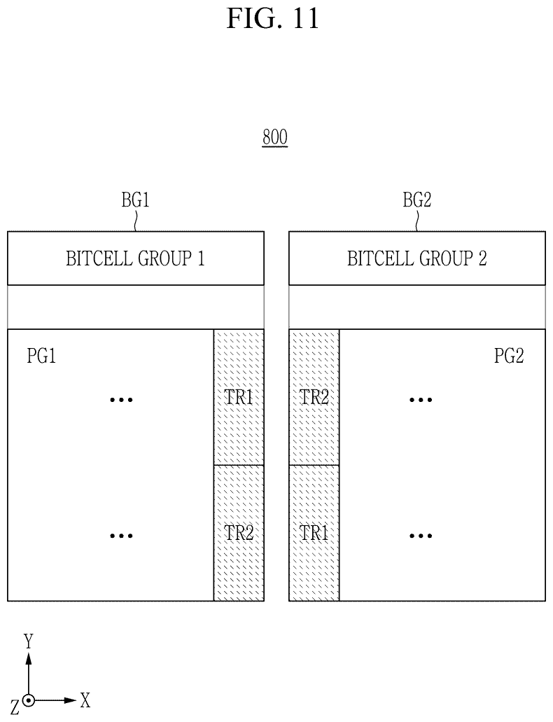

FIG. 11 to FIG. 13 illustrate a layout diagram of a memory device according to some embodiments.

Referring to FIG. 11, the memory device 800 may include a first bit cell group BG1 and a second bit cell group BG2 including a predetermined number of bit cells arranged adjacently in the first direction X. For example, each of first bit cell group BG1 and second bit cell group BG2 arranged adjacent to each other in the first direction X may include a plurality of bit cells arranged adjacent to each other in the first direction X.

The memory device 800 may include a first peripheral circuit group PG1 and a second peripheral circuit group PG2 including a predetermined number of standard cells arranged adjacently in the first direction X and the second direction Y. For example, each of the first peripheral circuit group PG1 and the second peripheral circuit group PG2 arranged adjacent to each other in the first direction X may include a plurality of standard cells arranged adjacently in the first direction X and the second direction Y.

The first peripheral circuit group PG1 may correspond to the first bit cell group BG1, and the second peripheral circuit group PG2 may correspond to the second bit cell group BG2. The first peripheral circuit group PG1 and the first bit cell group BG1 may be aligned with each other in the second direction Y, and may have a same width in the first direction X. The second peripheral circuit group PG2 and the second bit cell group BG2 may be aligned with each other in the second direction Y, and may have a same width in the first direction X.

In some embodiments, the first peripheral circuit group PG1 and the second peripheral circuit group PG2 may include a P-type transistor TR1 and/or an N-type transistor TR2. The first peripheral circuit group PG1 and the second peripheral circuit group PG2 may include a P-type transistor TR1 and/or an N-type transistor TR2 aligned in the second direction Y positioned at a boundary between the first peripheral circuit group PG1 and the second peripheral circuit group PG2. Herein, one peripheral circuit group is shown as including transistors of different types, but one peripheral circuit group may include transistors of a same type. For example, the first peripheral circuit group PG1 may include P-type transistors TR1 aligned in the second direction Y at the interface with the second peripheral circuit group PG2, and the second peripheral circuit group PG2 may include N-type transistors TR2 aligned in the second direction Y at the interface with the first peripheral circuit group PG1. In some embodiments, in an interface where the first peripheral circuit group PG1 and the second peripheral circuit group PG2 face each other, types of transistors included in the first peripheral circuit group PG1 and the second peripheral circuit group PG2 may be different from each other.

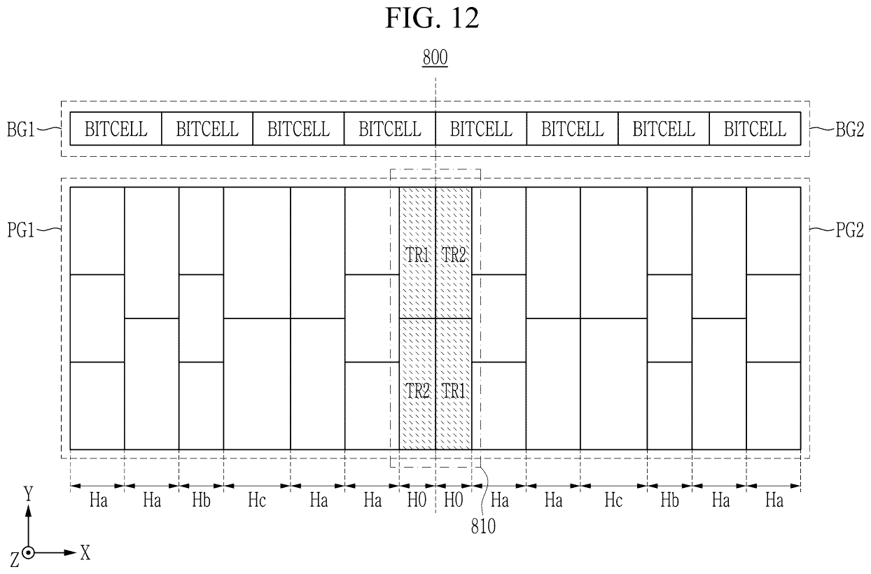

Referring to FIG. 12, the first bit cell group BG1 and the second bit cell group BG2 may include a plurality of bit cells, and the first peripheral circuit group PG1 and the second peripheral circuit group PG2 may include a plurality of standard cells with different heights arranged in a plurality of rows. For example, the first peripheral circuit group PG1 may include standard cells of a first height Ha, a second height Hb, and a third height Hc, and the standard cells of the second peripheral circuit group PG2 may be arranged in a manner in which the standard cells of the first peripheral circuit group PG1 are flipped relative to the second direction Y. However, the disposition of the standard cells in each peripheral circuit group is not limited thereto.

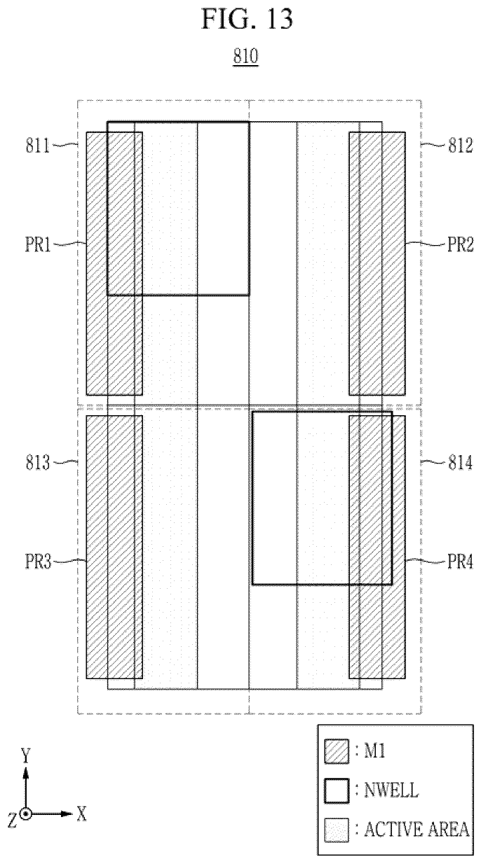

In some embodiments, the first peripheral circuit group PG1 and the second peripheral circuit group PG2 may include a P-type transistor TR1 and/or an N-type transistor TR2 positioned at an interface. The P-type transistor TR1 and N-type transistor TR2 positioned at the boundary between the first peripheral circuit group PG1 and the second peripheral circuit group PG2 may form one CMOS transistor by aligning the first peripheral circuit group PG1 and the second peripheral circuit group PG2 adjacent to each other. Specifically, as the first peripheral circuit group PG1 and the second peripheral circuit group PG2 are aligned adjacently in the first direction X, the P-type transistor TR1 and N-type transistor TR2 positioned at the boundary between the first peripheral circuit group PG1 and the second peripheral circuit group PG2 may form one CMOS transistor. This allows additional implementation of standard cells designed as CMOS transistors without increasing an area of the memory device, increasing the integration of standard cells in the memory device, thereby enabling additional area improvement. An internal structure of the transistors 810 positioned at the boundary between the first peripheral circuit group PG1 and the second peripheral circuit group PG2 will be described with reference to FIG. 13.

Referring to FIG. 13, a first transistor 811 and a second transistor 813 of the first peripheral circuit group PG1 and a first transistor 814 and a second transistor 812 of the second peripheral circuit group PG2 may be arranged adjacent to each other in the first direction X. Herein, the first transistors 811 and 814 may be P-type transistors, and the second transistors 812 and 813 may be N-type transistors, but the present disclosure is not limited thereto. For example, the transistors 811 and 813 positioned in the first peripheral circuit group PG1 are P-type transistors, and the transistors 812 and 814 positioned in the second peripheral circuit group PG2 are N-type transistors. The first transistor 811 of the first peripheral circuit group PG1 may share the first power rail PR1 with an adjacent standard cell in the first peripheral circuit group PG1. Herein, a power voltage may be applied to the first power rail PR1. The first transistor 811 of the first peripheral circuit group PG1 may share the third power rail PR3 with an adjacent standard cell in the first peripheral circuit group PG1. Herein, a ground voltage may be applied to the third power rail PR3. The second transistor 812 in the second peripheral circuit group PG2 may share the second power rail PR2 with an adjacent standard cell in the second peripheral circuit group PG2. Herein, a ground voltage may be applied to the second power rail PR2. The first transistor 814 in the second peripheral circuit group PG2 may share the fourth power rail PR4 with an adjacent standard cell in the second peripheral circuit group PG2. Herein, a power voltage may be applied to the fourth power rail PR4.

In some embodiments, the first transistor 811 of the first peripheral circuit group PG1 and the second transistor 812 of the second peripheral circuit group PG2 are positioned adjacent to each other in the first direction X, so that the first transistor 811 and the second transistor 812 may form a standard cell as a single CMOS transistor. In addition, the second transistor 813 of the first peripheral circuit group PG1 and the first transistor 814 of the second peripheral circuit group PG2 are positioned adjacent to each other in the first direction X, so that the second transistor 813 and 814 may form a standard cell as a single CMOS transistor.

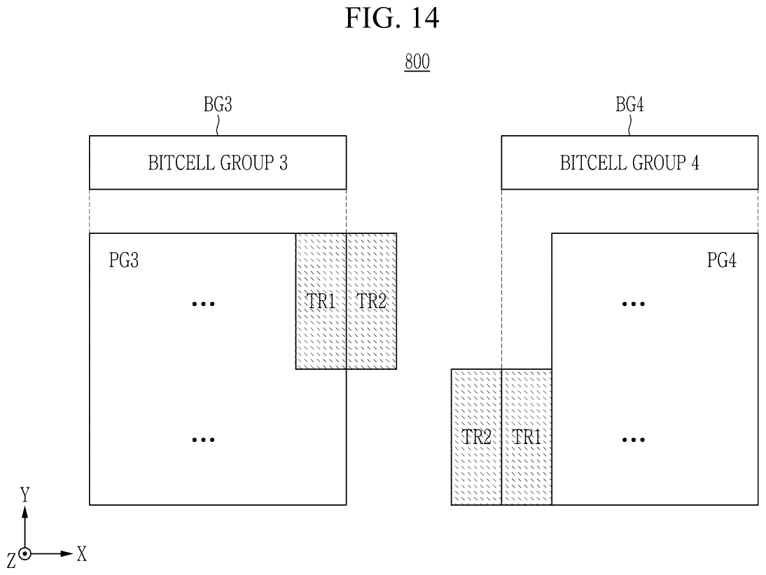

FIG. 14 illustrates a layout diagram of the memory device according to some embodiments.

In some embodiments, the peripheral circuit groups PG3 and PG4 may have different widths from the bit cell groups BG3 and BG4 in the first direction X. As described above in FIGS. 11 to 13, in some embodiments in which peripheral circuit groups are aligned adjacently to additionally form one standard cell, the peripheral circuit groups may further include a P-type transistor and an N-type transistor at an interface with another peripheral circuit group.

Referring to FIG. 14, the peripheral circuit groups PG3 and PG4 may be aligned with the bit cell groups BG3 and BG4 in the second direction Y. The third peripheral circuit group PG3 may correspond to the third bit cell group BG3, and the fourth peripheral circuit group PG4 may correspond to the fourth bit cell group BG4. The peripheral circuit groups PG3 and PG4 may include a plurality of standard cells arranged in a plurality of rows, and at least one row of the rows may include a P-type transistor and an N-type transistor at an interface with another peripheral circuits. For example, the third peripheral circuit group PG3 may include a P-type transistor and an N-type transistor in an interface with the fourth peripheral circuit group PG4 in a first row, and the fourth peripheral circuit group PG4 may include a P-type transistor and an N-type transistor at an interface with the third peripheral circuit group PG3 in a second row. Accordingly, by aligning the third peripheral circuit group PG3 and the fourth peripheral circuit group PG4 adjacent to each other, a standard cell may be additionally formed as a CMOS transistor.

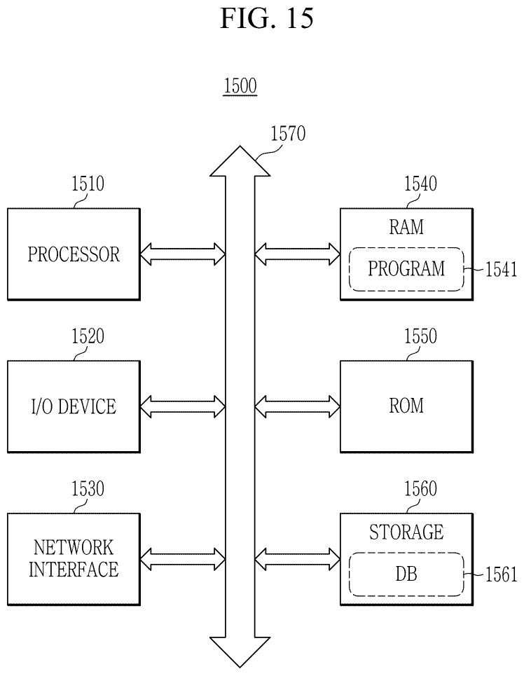

FIG. 15 illustrates a block diagram showing a computing system that manufactures a memory device according to some embodiments. At least some of the steps for manufacturing a memory device according to embodiments of the present disclosure may be performed in the computing system 1500.

Referring to FIG. 15, the computing system 1500 may be a fixed computing system such as a desktop computer, a workstation, or a server, or a portable computing system such as a laptop computer. The computing system 1500 include a processor 1510, input/output devices 1520, a network interface 1530, a random access memory (RAM) 1540, a read only memory (ROM) 1550, and a storage device 1560. The processor 1510, the input/output devices 1520, the network interface 1530, the RAM 1540, ROM 1550, and the storage device 1560 may communicate with each other through a bus 1570.

The processor 1510 may be referred to as a processing unit, and may include at least one core capable of executing an arbitrary instruction set, such as a microprocessor, an application processor (AP), a digital signal processor (DSP), or a graphic processing unit (GPU), for example. For example, the processor 1510 may access a memory, i.e., the RAM 1540 or the ROM 1550, through the bus 1570, and may execute instructions stored in the RAM 1540 or the ROM 1550.

The RAM 1540 may store a program 1541 or at least a portion thereof for manufacturing a memory device according to some embodiments of the present disclosure. For example, the program 1541 may include a semiconductor design tool, such as a logic synthesis tool and a P&R tool.

The program 1541 may cause the processor 1510 to perform at least some of operations for manufacturing the memory device of FIGS. 8 to 13. For example, operations for manufacturing the memory device of FIGS. 8 to 13 may include performing logic synthesis from RTL data written in HDL (hardware description language) or arranging and interconnecting standard cells. That is, the program 1541 may include a plurality of instructions executable by the processor 1510, and the instructions included in the program 1541 may cause the processor 1510 to perform at least some of the operations for manufacturing the memory device of FIGS. 8 to 13.

The storage device 1560 may not lose stored data even if a power supplied to the computing system 1500 is cut off. For example, the storage device 1560 may include a non-volatile memory device or a storage medium such as a magnetic tape, an optical disk, or a magnetic disk. The storage device 1560 may store program 1541 according to some embodiments of the present disclosure, and the program 1541 or at least a portion thereof may be loaded into the RAM 1540 from the storage device 1560 before the program 1541 is executed by the processor 1510. Alternatively, the storage device 1560 may store files written in a program language, and the program 1541 or at least a portion thereof generated from a file by a compiler, etc. may be loaded into the RAM 1540.

The storage device 1560 may store a database 1561, and the database 1561 may include information needed to design a semiconductor device. For example, the database 1561 may include a cell library of the standard cells of FIGS. 8 to 13. The cell library may include information related to logic cells included in the peripheral circuit group. For example, it may include function information, characteristic information, layout information, etc. of logic cells. Additionally, the storage device 1560 may store data to be processed by the processor 1510 or data processed by the processor 1510.

The input/output devices 1520 may include input devices such as keyboards and pointing devices, and may include output devices such as display devices and printers. The network interface 1530 may provide access to a network external to the computing system 1500.

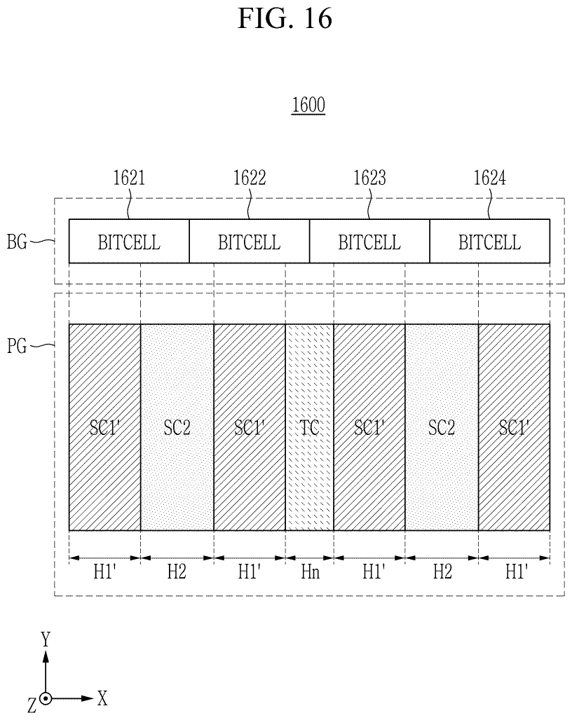

FIG. 16 illustrates a layout diagram of the memory device according to some embodiments.

As described above with reference to FIG. 4 and FIG. 5, in order to maintain the same width in the first direction X of the peripheral circuit group PG and the bit cell group BG, the heights of some of the standard cells SC may be greater than the height determined due to the driving force required for that standard cell. In some embodiments, in order to maintain the same width in the first direction X of the peripheral circuit group PG comprising standard cells and the bit cell group BG, the area of the bit cells 1621, 1622, 1623, 1624 (e.g., a width in the first direction X of the bit cells 1621, 1622, 1623, 1624) may need to be varied. This may result in an increase in the area of the memory device 1600.

In some embodiments, the bit cell group BG of the memory device 1600 may include bit cells 1621, 1622, 1623, 1624. In FIG. 16, the peripheral circuit group PG is shown to include standard cells of various standardized heights (e.g., H1′, H2) depending on the driving force, but is not limited thereto, and the peripheral circuit group PG may include standard cells of the same height. In some embodiments, the bit cell group BG of the memory device 1600 may include the bit cells 1621, 1622, 1623, 1624, and the peripheral circuit group PG may have a remaining space equal to the height Hn. That is, the width in the first direction X of the bit cells 1621, 1622, 1623, 1624 and the width in the first direction X of the standard cells SC may be different. The width in the first direction X of the bit cells 1621, 1622, 1623, 1624 may be longer or greater than the width in the first direction X of the standard cells SC. Here, the height Hn may be equal to the difference between the width in the first direction X of the bit cells 1621, 1622, 1623, 1624 and the width in the first direction X of the standard cells SC. Accordingly, the peripheral circuit group PG may have a remaining space equal to the height Hn.

In some embodiments, the peripheral circuit group PG may include a tap cell (TC) of height Hn. The tap cell (TC) according to some embodiments may be a non-standardized cell, wherein the size of the non-standardized cell may be not predetermined. The tap cell may provide well tapping by connecting the n-wells within the tap cell to a power supply voltage and the p-wells within the tap cell to a ground voltage to prevent leach-up of the standard cells. The tap cell TC may be implemented at different heights to maintain the same width in the first direction X of the peripheral circuit group PG and the bit cell group BG, i.e., the height Hn of the tap cell TC may be varied depending on the width in the first direction X of the remaining space. Additionally, the peripheral circuit group PG may also include a plurality of tap cells (TCs) depending on the length in the first direction X of the remaining space. In FIG. 16, the tap cell (TC) is shown disposed between standard cells within the peripheral circuit group (PG), but the position is not limited thereto, and the tap cell (TC) may be disposed at the edges of the peripheral circuit group (PG).

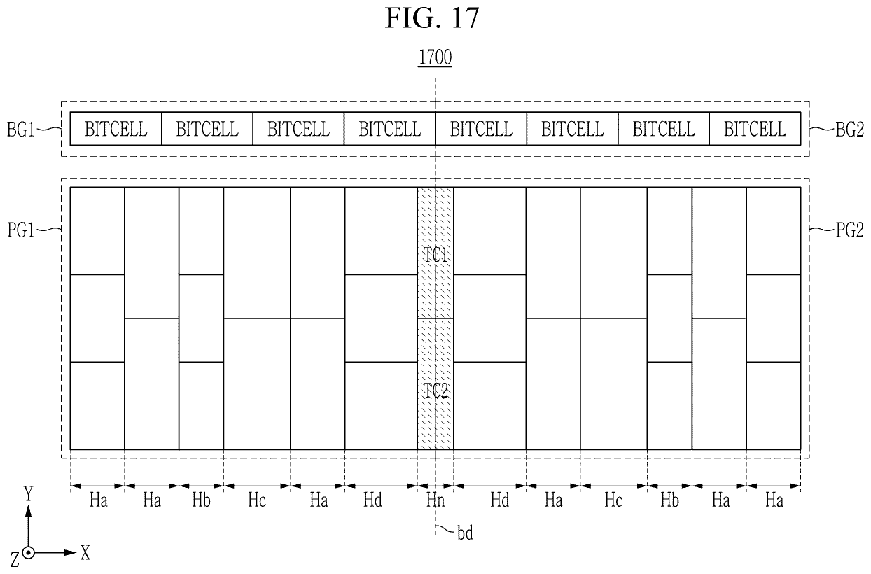

FIG. 17 is a layout diagram of a memory device according to some embodiments.

In some embodiments, the memory device 1700 may include a first bit cell group BG1 and a second bit cell group BG2 including a predetermined number of bit cells arranged adjacently in the first direction X. For example, each of first bit cell group BG1 and second bit cell group BG2 arranged adjacent to each other in the first direction X may include a plurality of bit cells arranged adjacent to each other in the first direction X.

The memory device 1700 may include a first peripheral circuit group PG1 and a second peripheral circuit group PG2 including a predetermined number of standard cells arranged adjacently in the first direction X and the second direction Y. For example, each of the first peripheral circuit group PG1 and the second peripheral circuit group PG2 arranged adjacent to each other in the first direction X may include a plurality of standard cells arranged adjacently in the first direction X and the second direction Y.

Referring to FIG. 17, the first bit cell group BG1 and the second bit cell group BG2 may include a plurality of bit cells, and the first peripheral circuit group PG1 and the second peripheral circuit group PG2 may include a plurality of standard cells with different heights arranged in a plurality of rows. For example, the first peripheral circuit group PG1 may include standard cells of a first height Ha, a second height Hb, a third height Hc, and a fourth height Hd, and the standard cells of the second peripheral circuit group PG2 may be arranged in a manner in which the standard cells of the first peripheral circuit group PG1 are flipped relative to the second direction Y. However, the disposition of the standard cells in each peripheral circuit group is not limited thereto.

In some embodiments, the width in the first direction X of the bit cells BITCELL in the first bit cell group BG1 and the second bit cell group BG2 and the width in the first direction X of the standard cells in the first peripheral circuit group PG1 and the second peripheral circuit group PG2 may be different. The width in the first direction X of the bit cells may be longer or greater than the width in the first direction X of the standard cells. The difference between the width in the first direction X of the bit cells and the width in the first direction X of the standard cells may be equal to the height Hn. Accordingly, the first peripheral circuit group PG1 and the second peripheral circuit group PG2 may have a remaining space equal to the height Hn.

In some embodiments, the first peripheral circuit group PG1 and the second peripheral circuit group PG2 may include tap cells TC1, TC2 located at the boundary bd. Here, the height Hn of the tap cells TC1, TC2 may be varied depending on the height of the rest of the remaining space. Further, the first peripheral circuit group PG1 and the second peripheral circuit group PG2 may further comprise tap cells located at the boundary bd according to the height of the remaining space.

As above, embodiments are disclosed in the drawings and specifications. In this specification, embodiments have been described using specific terms, but this is only used for the purpose of describing the technical idea of the present disclosure and is not used to limit the meaning or scope of the present disclosure as set forth in the patent claims. Therefore, a person of ordinary skill in the art will understand that various modifications and other equivalent embodiments of the present disclosure are possible. Consequently, the true technical protective scope of the present disclosure must be determined based on the technical spirit of the appended claims.

What is claimed is:

1. A memory device comprising:
a first bit cell group comprising a first plurality of bit cells; and
a first peripheral circuit group configured to write data to the first plurality of bit cells and read data from the first plurality of bit cells, wherein the first peripheral circuit group comprises a first type transistor and a second type transistor of a different type from the first type transistor, and wherein the first peripheral circuit group comprises a plurality of first standard cells adjacent to each other in a first direction and a first switch cell comprising one of the first type transistor and the second type transistor.

2. The memory device of claim 1, further comprising:
a plurality of power rails on a boundary of the plurality of first standard cells, wherein the plurality of power rails are configured to extend in a second direction perpendicular to the first direction, and wherein the plurality of power rails are configured to apply a first power voltage and a second power voltage different from the first power voltage to each of the plurality of first standard cells, and
the first switch cell is between a first power rail and a second power rail among the plurality of power rails, wherein the first power rail and the second power rail are adjacent to each other.

3. The memory device of claim 2, wherein the first switch cell is configured to receive a power voltage from an external source and to transmit the power voltage as the first power voltage to at least one of the first power rail or the second power rail.

4. The memory device of claim 1, further comprising:
a second bit cell group comprising a second plurality of bit cells; and
a second peripheral circuit group configured to write data to the second plurality of bit cells and read data from the second plurality of bit cells, wherein the second peripheral circuit group comprises a plurality of second standard cells including the first type transistor and the second type transistor and a second switch cell comprising one of the first type transistor and the second type transistor, and wherein the second peripheral circuit group is adjacent to the first peripheral circuit group in the first direction.

5. The memory device of claim 4, wherein the first switch cell and the second switch cell are adjacent to a boundary between the first peripheral circuit group and the second peripheral circuit group.

6. The memory device of claim 5, wherein types of transistors of the first switch cell and the second switch cell are different from each other.

7. The memory device of claim 1, wherein the first type transistor and the second type transistor are gate-all-around (GAA) transistors.

8. The memory device of claim 7, wherein the gate all-around transistors are multi-bridge channel (MBC) transistors.

9. The memory device of claim 1, wherein the first plurality of bit cells are static random access memory (SRAM) cells.

10. The memory device of claim 1, wherein the first type transistor is a P-type transistor, and wherein the second type transistor is an N-type transistor.

11. The memory device of claim 1, wherein the first peripheral circuit group is aligned with the first bit cell group in a second direction perpendicular to the first direction, and wherein a width of the first peripheral circuit group in the first direction and a width of the first bit cell group in the first direction are equal.

12. A memory device comprising:
a bit cell group comprising a plurality of bit cells; and
a peripheral circuit group, wherein a width of the peripheral circuit group in a first direction is equal to a width of the bit cell group in the first direction, wherein the peripheral circuit group is aligned with the bit cell group in a second direction perpendicular to the first direction, and wherein the peripheral circuit group comprises:
a plurality of power rails that are spaced apart from each other in the first direction and extend in the second direction,
a plurality of first active regions between a first power rail and a second power rail among the plurality of power rails, wherein the plurality of first active regions are spaced apart from each other in the first direction and extend in the second direction and comprise a first transistor and a second transistor having a different type from the first transistor, wherein the first transistor and the second transistor are electrically connected to a first bit cell and a second bit cell, respectively, among the plurality of bit cells,
a plurality of second active regions between a third power rail and a fourth power rail among the plurality of power rails, wherein the plurality of second active regions are spaced apart from each other in the first direction and extend in the second direction and comprise a third transistor and a fourth transistor having a different type from the third transistor, wherein the third transistor and the fourth transistor are electrically connected to a third bit cell and a fourth bit cell, respectively, among the plurality of bit cells, and
a third active region between the second power rail and third power rail, wherein the second power rail and the third power rail are adjacent to each other, wherein the third active region is spaced apart from the second power rail and the third power rail in the first direction by a same distance in the first direction and extends in the second direction, and wherein the third active region comprises a fifth transistor.

13. The memory device of claim 12, further comprising:
a plurality of fourth active regions between a fifth power rail and a sixth power rail among the plurality of power rails, wherein the plurality of fourth active regions are spaced apart from each other in the first direction and extend in the second direction and comprise a sixth transistor and a seventh transistor having a different type from the sixth transistor, wherein the sixth transistor and the seventh transistor are electrically connected to a sixth bit cell and a seventh bit cell, respectively, among the plurality of bit cells;
a plurality of fifth active regions between a seventh power rail and a eighth power rail among the plurality of power rails, wherein the plurality of fifth active regions are spaced apart from each other in the first direction and extend in the second direction and comprise an eighth transistor and a ninth transistor having a different type from the eighth transistor, wherein the eighth transistor and the ninth transistor are electrically connected to an eighth bit cell and a ninth bit cell, respectively, among the plurality of bit cells; and
a sixth active region between the sixth power rail and the seventh power rail, wherein the sixth power rail and the seventh power rail are adjacent to each other, wherein the sixth active region is spaced apart from the sixth power rail and the seventh power rail in the first direction by a same distance, and wherein the sixth active region comprises a tenth transistor.

14. The memory device of claim 12, wherein the fifth transistor is configured to receive a power voltage from an external source and to transmit a first power voltage having a same voltage level as the power voltage to at least one of the second power rail or the third power rail.

15. The memory device of claim 14, wherein the second power rail is configured to apply the first power voltage to the first transistor.

16. The memory device of claim 12, wherein the fifth transistor is a P-type transistor.

17. The memory device of claim 12, wherein the plurality of bit cells are static random access memory (SRAM) cells.

18. A memory device comprising:
a plurality of bit cells having a first width in a first direction;
a plurality of standard cells having a second width in the first direction different from the first width, wherein the plurality of standard cells are electrically connected to the plurality of bit cells through bit lines, wherein the plurality of standard cells comprise a plurality of active regions, wherein each of the plurality of active regions comprises a first type transistor and a second type transistor different from the first type transistor, wherein a height in the first direction of each of the plurality of standard cells is based on a width of a respective active region of the plurality of active regions in the first direction, and wherein the plurality of standard cells are aligned in the first direction; and
a non-standardized cell aligned with the plurality of standard cells in the first direction and having a height equal to a difference between the first width and the second width.

19. The memory device of claim 18, wherein a first standard cell of the plurality of standard cells has a first height in the first direction, and wherein a second standard cell of the plurality of standard cells has a second height in the first direction that is different from the first height.

20. The memory device of claim 18, wherein the non-standardized cell is a tap cell or a switch cell comprising a first active region that comprises one of the first type transistor and the second type transistor.
